(19) United States
(12) Patent Application Publication
(10) Pub. No.: US 2026/0179580 A1
(43) Pub. Date: Jun. 25, 2026

(54) SHIFT REGISTER, DRIVING METHOD THEREFOR, AND DISPLAY PANEL

(71) Applicant: Kunshan Govisionox Optoelectronics Co., Ltd., Kunshan (CN)

(72) Inventors: Peixuan CAO, Kunshan (CN); Siwei XU, Kunshan (CN); Huiling LU, Kunshan (CN); Siming HU, Kunshan (CN)

(73) Assignee: Kunshan Govisionox Optoelectronics Co., Ltd., Kunshan (CN)

(21) Appl. No.: 19/457,068

(22) Filed: Jan. 22, 2026

Related U.S. Application Data
(63) Continuation of application No. PCT/CN2024/072499, filed on Jan. 16, 2024.

(30) Foreign Application Priority Data
Jul. 24, 2023 (CN) 202310911895.3

(51) Int. Cl. G09G 3/36; G09G 3/20; G11C 19/28

(52) U.S. Cl. CPC G09G 3/3677; G09G 3/20; G11C 19/28

(57) ABSTRACT

The present application discloses a shift register, a driving method therefor, and a display panel. The shift register includes: a first input module, a second input module, an interlock module, a first output module, and a second output module. The first input module transmits a first level to a first node. The second input module transmits a second level to a second node. The interlock module controls a level of one of the first node and the second node, in response to a level of the other one. The first output module transmits a level of a clock signal applied to a second clock signal terminal to an output terminal, in response to the first level of the first node. The second output module transmits a power supply signal to the output terminal, in response to the second level of the second node.

### CROSS-REFERENCE TO RELATED APPLICATIONS

The present application a continuation of International Application No. PCT/CN 2024/072499 filed on January 16, 2024, which claims priority to Chinese Patent Application No. 202310911895.3, filed on July 24, 2023. All of the aforementioned patent applications are hereby incorporated by reference in their entireties.

### FIELD

The present application relates to the field of display technologies, and for example, relates to a shift register, a driving method therefor, and a display panel.

### BACKGROUND

A display panel typically includes a scan driver circuit that includes a multi-stage shift register. The multi-stage shift register is used to provide scan signals to pixel circuits of a plurality of rows of sub-pixels, respectively, to achieve row-by-row scanning of the plurality of rows of sub-pixels. Based on this, providing a stable and reliable shift register is key to ensuring a display effect of the display panel.

### SUMMARY

The present application discloses a shift register, a driving method therefor, and a display panel, to provide a stable and reliable shift register.

One or more embodiments of the present application disclose a shift register. The shift register includes:

a first input module, electrically connected to at least an input terminal and a first node, the first input module being configured to transmit a first level to the first node under the control of a signal applied to the input terminal;

a second input module, electrically connected to at least the input terminal, a second node, and a first clock signal terminal, the second input module being configured to transmit a second level of a clock signal applied to the first clock signal terminal to the second node under the control of at least the signal applied to the input terminal and the clock signal applied to the first clock signal terminal;

an interlock module, electrically connected to at least the first node and the second node, the interlock module being configured to transmit a third level logically opposite to the second level to the second node, in response to at least the first level of the first node, and transmit a fourth level logically opposite to the first level to the first node, in response to at least the second level of the second node;

a first output module, electrically connected to a second clock signal terminal and an output terminal, the first output module being configured to transmit a level of a clock signal applied to the second clock signal terminal to the output terminal, in response to the first level of the first node; and

a second output module, electrically connected to the second node, a first power supply signal terminal, and the output terminal, the second output module being configured to transmit a level of a power supply signal applied to the first power supply signal terminal to the output terminal, in response to the second level of the second node.

One or more embodiments of the present application disclose a display panel, including a scan driver circuit. The scan driver circuit includes a plurality of cascaded shift registers each including a shift register according to any one of the above-described embodiments.

One or more embodiments of the present application disclose a driving method for a shift register, for use in driving a shift register according to any one of the above-described embodiments. The driving method includes:

in a first phase, the first input module transmits a first level to the first node under the control of a signal applied to the input terminal, the interlock module transmits a third level to the second node, in response to at least the first level of the first node, and the first output module transmits a level of a clock signal applied to the second clock signal terminal to the output terminal, in response to the first level of the first node;

in a second phase, the levels of the first node and the second node remain unchanged, and the first output module transmits the level of the clock signal applied to the second clock signal terminal to the output terminal, in response to the first level of the first node;

in a third phase, the second input module transmits the second level of the clock signal applied to the first clock signal terminal to the second node under the control of at least the signal applied to the input terminal and the clock signal applied to the first clock signal terminal, the interlock module transmits a fourth level to the first node, in response to at least the second level of the second node, and the second output module transmits the level of the power supply signal applied to the first power supply signal terminal to the output terminal, in response to the second level of the second node; and

in a fourth phase, the levels of the first node and the second node remain unchanged, and the second output module transmits the level of the power supply signal applied to the first power supply signal terminal to the output terminal, in response to the second level of the second node.

According to the shift register, the driving method therefor, and the display panel disclosed in the present application, the first input module, the second input module, the interlock module, the first output module, and the second output module are included. The first input module is configured to transmit the first level to the first node under the control of the signal applied to the input terminal. The second input module is configured to transmit the second level of the clock signal applied to the first clock signal terminal to the second node under the control of at least the signal applied to the input terminal and the clock signal applied to the first clock signal terminal. The interlock module is configured to transmit the third level logically opposite to the second level to the second node, in response to the first level of the first node, and transmit the fourth level logically opposite to the first level to the first node, in response to at least the second level of the second node. The first output module is configured to transmit the level of the clock signal applied to the second clock signal terminal to the output terminal, in response to the first level of the first node. The second output module is configured to transmit the level of the power supply signal applied to the first power supply signal terminal to the output terminal, in response to the second level of the second node. Therefore, by alternately outputting the level of the clock signal applied to the second clock signal terminal and the level of the power supply signal applied to the first power supply signal terminal, reliable and stable output of a scan signal can be achieved, thereby ensuring a display effect of the display panel.

### BRIEF DESCRIPTION OF THE DRAWINGS

To describe the embodiments of the present application or the background more clearly, the drawings for the embodiments of the present application or the background are described below.

FIG. 1 is a schematic structural diagram of a shift register according to an embodiment of the present application.

FIG. 2 is a schematic structural diagram of each module of a shift register according to an embodiment of the present application.

FIG. 3 is a timing diagram of the shift register shown in FIG. 2.

FIG. 4 is a schematic structural diagram of another shift register according to an embodiment of the present application.

FIG. 5 is a schematic structural diagram of another shift register according to an embodiment of the present application.

FIG. 6 is a schematic structural diagram of another shift register according to an embodiment of the present application.

FIG. 7 is a schematic structural diagram of another shift register according to an embodiment of the present application.

FIG. 8 is a schematic structural diagram of another shift register according to an embodiment of the present application.

FIG. 9 is a schematic structural diagram of another shift register according to an embodiment of the present application.

FIG. 10 is a schematic structural diagram of each module of another shift register according to an embodiment of the present application.

FIG. 11 is a flowchart of a driving method for a shift register according to an embodiment of the present application.

FIG. 12 is a schematic structural diagram of a scan driver circuit according to an embodiment of the present application.

FIG. 13 is a schematic structural diagram of a display panel according to an embodiment of the present application.

### DETAILED DESCRIPTION OF THE EMBODIMENTS

The embodiments of the present application will be clearly and completely described below with reference to the accompanying drawings for the embodiments of the present application. It is clear that the embodiments described are merely some rather than all of the embodiments of the present application.

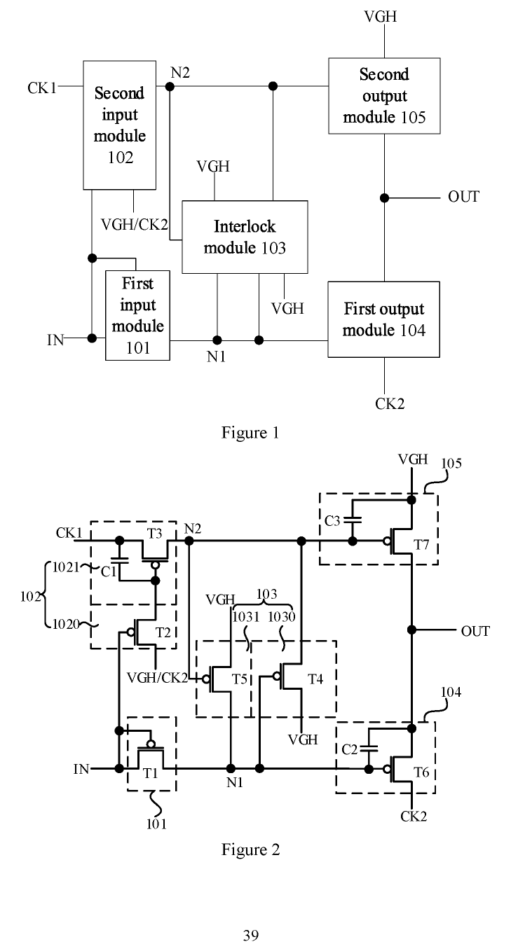

As an optional implementation of the disclosure of the present application, an embodiment of the present application discloses a shift register. As shown in FIG. 1, FIG. 1 is a schematic structural diagram of a shift register according to an embodiment of the present application. The shift register includes a first input module 101, a second input module 102, an interlock module 103, a first output module 104, and a second output module 105.

The first input module 101 is electrically connected to at least an input terminal IN and a first node N1. The first input module 101 is configured to transmit a first level to the first node N1 under the control of a signal applied to the input terminal IN. In one or more embodiments, under the control of the level of the signal applied to the input terminal IN that is a first level, the first input module 101 is turned on and transmits the first level to the first node N1; and under the control of the level of the signal applied to the input terminal IN that is a level logically (or polarly) opposite to the first level, the first input module 101 is turned off and stops transmitting the first level to the first node N1. For example, the first level is a low level, and the level logically opposite to the first level is a high level. In one or more embodiments, the first level is a high level, and the level logically opposite to the first level is a low level.

The second input module 102 is electrically connected to at least the input terminal IN, a first clock signal terminal CK1, and a second node N2. The second input module 102 is configured to transmit a second level of a clock signal applied to the first clock signal terminal CK1 to the second node N2 under the control of at least the signal applied to the input terminal IN and the clock signal applied to the first clock signal terminal CK1. In one or more embodiments, under the control of the level of the signal applied to the input terminal IN that is the first level, the second input module 102 stops transmitting the level of the clock signal applied to the first clock signal terminal CK1 to the second node N2. Under the control of the level of the signal applied to the input terminal IN that is the level logically opposite to the first level and the level of the clock signal applied to the first clock signal terminal CK1 that is the second level, the second input module 102 transmits the second level of the clock signal applied to the first clock signal terminal CK1 to the second node N2. For example, the second level and the first level are logically the same. For example, both the second level and the first level may be low levels.

The interlock module 103 is electrically connected to at least the first node N1 and the second node N2. The interlock module 103 is configured to transmit a third level logically opposite to the second level to the second node N2, in response to at least the first level of the first node N1, and transmit a fourth level logically opposite to the first level to the first node N1, in response to at least the second level of the second node N2. The third level is a level logically or polarly opposite to the second level. For example, the third level is a low level, and the second level is a high level. In one or more embodiments, the third level is a high level, and the second level is a low level. The fourth level is a level logically or polarly opposite to the first level. For example, the fourth level is a low level, and the first level is a high level. In one or more embodiments, the fourth level is a high level, and the first level is a low level. The interlock module 103 may time-divisionally transmit the third level to the second node N2 and the fourth level to the first node N1.

The first output module 104 is electrically connected to a second clock signal terminal CK2 and an output terminal OUT. The first output module 104 is configured to transmit a level of a clock signal applied to the second clock signal terminal CK2 to the output terminal OUT, in response to the first level of the first node N1. For example, the first output module 104 is turned on and transmits the level of the clock signal applied to the second clock signal terminal CK2 to the output terminal OUT, in response to the first level of the first node N1; and is turned off and stops transmitting the level of the clock signal applied to the second clock signal terminal CK2 to the output terminal OUT, in response to the fourth level of the first node N1. The first level may be a turn-on level for the first output module 104, and the fourth level may be a turn-off level for the first output module 104.

The second output module 105 is electrically connected to the second node N2, a first power supply signal terminal VGH, and the output terminal OUT. The second output module 105 is configured to transmit a level of a power supply signal applied to the first power supply signal terminal VGH to the output terminal OUT, in response to the second level of the second node N2. For example, the second output module 105 is turned on and transmits the level of the power supply signal applied to the first power supply signal terminal VGH to the output terminal OUT, in response to the second level of the second node N2. The second output module 105 is turned off and stops transmitting the level of the power supply signal applied to the first power supply signal terminal VGH to the output terminal OUT, in response to the third level of the second node N2. The second level may be a turn-on level for the second output module 105, and the third level may be a turn-off level for the second output module 105. For example, the first output module 104 and the second output module 105 may be turned on in a time-division manner, instead of being turned on simultaneously. For example, the level of the power supply signal applied to the first power supply signal terminal VGH may be logically opposite to the second level.

In one or more embodiments, the clock signal(For example the first clock signal) applied to the first clock signal terminal CK1 and the clock signal(For example the second clock signal) applied to the second clock signal terminal CK2 have the same frequency but opposite phases. For example, both the first clock signal and the second clock signal include pulse signals with alternating high and low levels.

In one or more embodiments, a control terminal of the first input module 101 is electrically connected to the input terminal IN, and a second terminal of the first input module 101 is electrically connected to the first node N1.

In one or more embodiments, a first terminal of the first output module 104 is electrically connected to the second clock signal terminal CK2, a control terminal of the first output module 104 is electrically connected to the first node N1, and a second terminal of the first output module 104 is electrically connected to the output terminal OUT.

In one or more embodiments, a first terminal of the second output module 105 is electrically connected to the first power supply signal terminal VGH, a control terminal of the second output module 105 is electrically connected to the second node N2, and a second terminal of the second output module 105 is electrically connected to the output terminal OUT.

In some embodiments of the present application, as shown in FIG. 2, FIG. 2 is a schematic structural diagram of each module of a shift register according to an embodiment of the present application. For example, the first input module 101 is electrically connected to the input terminal IN and the first node N1, and a first terminal of the first input module 101 is electrically connected to the input terminal IN. The first input module 101 is configured to transmit the first level (e.g., a low level) of the signal applied to the input terminal IN to the first node N1 under the control of the signal applied to the input terminal IN.

In one or more embodiments, the first input module 101 includes a first transistor T1. A gate and a first electrode of the first transistor T1 are electrically connected to the input terminal IN, and a second electrode of the first transistor T1 is electrically connected to the first node N1. For example, the first transistor T1 may be a dual-gate transistor.

In one or more embodiments, the second input module 102 includes a first input unit 1020 and a second input unit 1021. A control terminal of the first input unit 1020 is electrically connected to the input terminal IN, and a first terminal of the first input unit 1020 is electrically connected to the first power supply signal terminal VGH or the second clock signal terminal CK2. The first input unit 1020 is configured to transmit the level of the power supply signal applied to the first power supply signal terminal VGH or the clock signal applied to the second clock signal terminal CK2 to the second input unit 1021 under the control of the signal applied to the input terminal IN. The second input unit 1021 is electrically connected to a second terminal of the first input unit 1020, the second node N2, and the first clock signal terminal CK1. The second input unit 1021 is configured to transmit the second level of the clock signal applied to the first clock signal terminal CK1 to the second node N2 under the control of a level of the second terminal of the first input unit 1020 and the clock signal applied to the first clock signal terminal CK1.

In one or more embodiments, a first terminal of the second input unit 1021 is electrically connected to the first clock signal terminal CK1, a control terminal of the second input unit 1021 is electrically connected to the second terminal of the first input unit 1020, and a second terminal of the second input unit 1021 is electrically connected to the second node N2.

The first input unit 1020 is turned on and transmits the level of the power supply signal applied to the first power supply signal terminal VGH or the level of the clock signal applied to the second clock signal terminal CK2 (the level is a turn-off level for the second input unit 1021 and is logically opposite to the second level) to the second input unit 1021 via the second terminal of the first input unit 1020 under the control of the level of the signal applied to the input terminal IN that is the first level, thereby turning off the second input unit 1021. The first input unit 1020 is turned off and stops transmitting the level of the power supply signal applied to the first power supply signal terminal VGH or the clock signal applied to the second clock signal terminal CK2 to the second input unit 1021 under the control of the level of the signal applied to the input terminal IN that is a level logically opposite to the first level. The second input unit 1021 is turned on and transmits the second level of the clock signal applied to the first clock signal terminal CK1 to the second node N2 under the control of the level of the clock signal applied to the first clock signal terminal CK1 that is the second level (which may be a turn-on level for the second input unit 1021).

In one or more embodiments, the first input unit 1020 includes a second transistor T2. A gate of the second transistor T2 is electrically connected to the input terminal IN, a first electrode of the second transistor T2 is electrically connected to the first power supply signal terminal VGH or the second clock signal terminal CK2, and a second electrode of the second transistor T2 is the second terminal of the first input unit 1020. For example, the second transistor T2 may be a dual-gate transistor.

In one or more embodiments, the second input unit 1021 includes a third transistor T3 and a first capacitor C1. A gate of the third transistor T3 is electrically connected to the second terminal of the first input unit 1020, a first electrode of the third transistor T3 is electrically connected to the first clock signal terminal CK1, and a second electrode of the third transistor T3 is electrically connected to the second node N2. A first electrode of the first capacitor C1 is electrically connected to the first electrode of the third transistor T3, and a second electrode of the first capacitor C1 is electrically connected to the gate of the third transistor T3. For example, the third transistor T3 may be a dual-gate transistor.

In one or more embodiments, the interlock module 103 includes a first regulation unit 1030 and a second regulation unit 1031. The first regulation unit 1030 is electrically connected to at least the first power supply signal terminal VGH, the first node N1, and the second node N2. The first regulation unit 1030 transmits the level of the power supply signal applied to the first power supply signal terminal VGH as the third level to the second node N2, in response to at least the first level of the first node N1. The second regulation unit 1031 is electrically connected to at least the first power supply signal terminal VGH, the first node N1, and the second node N2. The second regulation unit 1031 transmits the level of the power supply signal applied to the first power supply signal terminal VGH as the fourth level to the first node N1, in response to at least the second level of the second node N2.

The first regulation unit 1030 is turned on and transmits the level of the power supply signal applied to the first power supply signal terminal VGH as the third level to the second node N2, in response to at least the first level of the first node N1. The first regulation unit 1030 is turned off and stops transmitting the level of the power supply signal applied to the first power supply signal terminal VGH as the third level to the second node N2, in response to at least the fourth level of the first node N1. The first level may be a turn-on level for the first regulation unit 1030, and the fourth level may be a turn-off level for the first regulation unit 1030.

The second regulation unit 1031 is turned on and transmits the level of the power supply signal applied to the first power supply signal terminal VGH as the fourth level to the first node N1, in response to at least the second level of the second node N2. The second regulation unit 1031 is turned off and stops transmitting the level of the power supply signal applied to the first power supply signal terminal VGH as the fourth level to the first node N1, in response to at least the third level of the second node N2. The second level may be a turn-on level for the second regulation unit 1031, and the third level may be a turn-off level for the second regulation unit 1031.

In one or more embodiments, the first regulation unit 1030 includes a fourth transistor T4. A gate of the fourth transistor T4 is electrically connected to the first node N1, a first electrode of the fourth transistor T4 is electrically connected to the first power supply signal terminal VGH, and a second electrode of the fourth transistor T4 is electrically connected to the second node N2. For example, the fourth transistor T4 may be a dual-gate transistor.

In one or more embodiments, the second regulation unit 1031 includes a fifth transistor T5. A gate of the fifth transistor T5 is electrically connected to the second node N2, a first electrode of the fifth transistor T5 is electrically connected to the first power supply signal terminal VGH, and a second electrode of the fifth transistor T5 is electrically connected to the first node N1. For example, the fifth transistor T5 may be a dual-gate transistor.

In one or more embodiments, the first output module 104 includes a sixth transistor T6. A gate of the sixth transistor T6 is electrically connected to the first node N1, a first electrode of the sixth transistor T6 is electrically connected to the second clock signal terminal CK2, and a second electrode of the sixth transistor T6 is electrically connected to the output terminal OUT.

In one or more embodiments, the first output module 104 further includes a second capacitor C2. A first electrode of the second capacitor C2 is electrically connected to the second electrode of the sixth transistor T6, and a second electrode of the second capacitor C2 is electrically connected to the gate of the sixth transistor T6.

In one or more embodiments, the second output module 105 includes a seventh transistor T7. A gate of the seventh transistor T7 is electrically connected to the second node N2, a first electrode of the seventh transistor T7 is electrically connected to the first power supply signal terminal VGH, and a second electrode of the seventh transistor T7 is electrically connected to the output terminal OUT.

In one or more embodiments, the second output module 105 further includes a third capacitor C3. A first electrode of the third capacitor C3 is electrically connected to the first electrode of the seventh transistor T7, and a second electrode of the third capacitor C3 is electrically connected to the gate of the seventh transistor T7.

FIG. 2 merely illustrates an example in which the first transistor T1 to the seventh transistor T7 are PMOS transistors, but the present application is not limited thereto. In some other embodiments, the first transistor T1 to the seventh transistor T7 may be NMOS transistors, etc. For example, a part of the first transistor T1 to the seventh transistor T7 may be NMOS transistors, and the rest may be PMOS transistors. A difference between the NMOS transistor and the PMOS transistor lies in that the PMOS transistor is turned on when a gate is at a low level, and is turned off when the gate is at a high level, while the NMOS transistor is turned on when a gate is at a high level, and is turned off when the gate is at a low level.

Operational phases of the shift register within one frame of image displayed include a first phase t1, a second phase t2, a third phase t3, and a fourth phase t4.

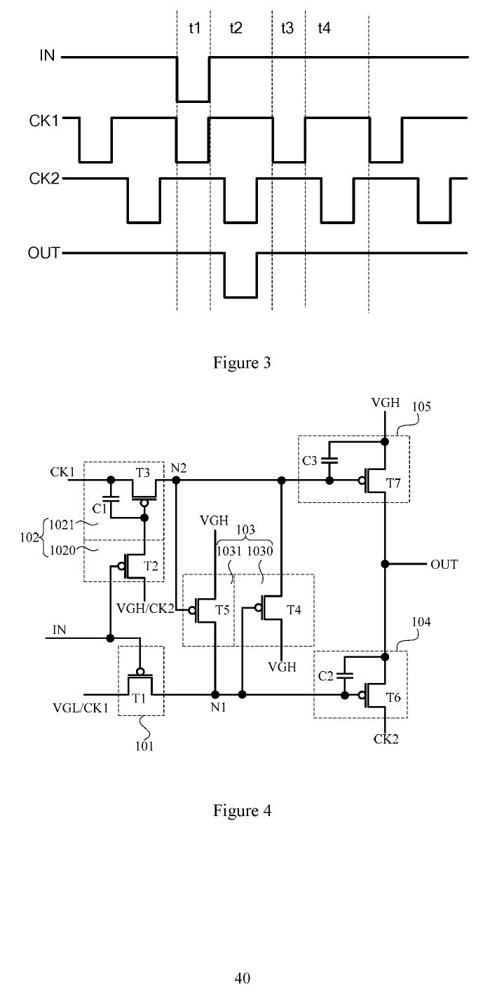

In one or more embodiments, as shown in FIG. 3, FIG. 3 is a timing diagram of the shift register shown in FIG. 2. In the first phase t1, the level of the clock signal applied to the first clock signal terminal CK1 is the second level (e.g., a low level), the level of the clock signal applied to the second clock signal terminal CK2 is the level logically opposite to the second level (e.g., a high level), and the level of the signal applied to the input terminal IN is the first level (e.g., a low level).

In the first phase t1, the first input module 101 is turned on and transmits the first level to the first node N1 under the control of the level of the signal applied to the input terminal IN that is the first level. The second input module 102 stops transmitting the level of the clock signal applied to the first clock signal terminal CK1 to the second node N2 under the control of at least the signal applied to the input terminal IN and the clock signal applied to the first clock signal terminal CK1. The interlock module 103 transmits the third level logically opposite to the second level to the second node N2, in response to at least the first level of the first node N1. The first output module 104 transmits the level of the clock signal applied to the second clock signal terminal CK2 to the output terminal OUT, in response to the first level of the first node N1. The second output module 105 is turned off and stops transmitting the level of the power supply signal applied to the first power supply signal terminal VGH to the output terminal OUT, in response to the third level of the second node N2.

As shown in FIG. 2, under the control of the signal applied to the input terminal IN that is the first level (e.g., a low level), the first input module 101 (e.g., the first transistor T1) is turned on, and the first input unit 1020 (e.g., the second transistor T2) is turned on. The turned-on first input module 101 (e.g., the first transistor T1) transmits the level of the signal applied to the input terminal IN that is the first level (e.g., a low level) to the first node N1. The turned-on first input unit 1020 (e.g., the second transistor T2) transmits the level (the level logically opposite to the second level, e.g., a high level) of the power supply signal applied to the first power supply signal terminal VGH or the clock signal applied to the second clock signal terminal CK2 to the second terminal of the first input unit 1020. After the second input unit 1021 (e.g., the gate of the third transistor T3) receives the level (e.g., a high level) of the second terminal of the first input unit 1020, the second input unit 1021 (e.g., the third transistor T3) is turned off and stops transmitting the level of the clock signal applied to the first clock signal terminal CK1 to the second node N2.

The first regulation unit 1030 (e.g., the fourth transistor T4) is turned on and transmits the level (e.g., a high level) of the power supply signal applied to the first power supply signal terminal VGH as the third level to the second node N2, in response to the first level (e.g., a low level) of the first node N1, and the second output module 105 (e.g., the seventh transistor T7) is turned off and stops transmitting the level of the power supply signal applied to the first power supply signal terminal VGH to the output terminal OUT, in response to the third level (e.g., a high level) of the second node N2. The second regulation unit 1031 (e.g., the fifth transistor T5) is turned off and stops transmitting the level of the power supply signal applied to the first power supply signal terminal VGH as the fourth level to the first node N1, in response to the third level (e.g., a high level) of the second node N2, and the first node N1 maintains at the first level (e.g., a low level), and the first output module 104 (e.g., the sixth transistor T6) is turned on and transmits the level of the clock signal applied to the second clock signal terminal CK2 to the output terminal OUT, in response to the first level (e.g., a low level) of the first node N1.

In one or more embodiments, as shown in FIG. 3, in the second phase t2, the level of the clock signal applied to the first clock signal terminal CK1 is the level logically opposite to the second level (e.g., a high level). The level of the clock signal applied to the second clock signal terminal CK2 changes from the level logically opposite to the second level (e.g., a high level) to the second level (e.g., a low level), and then back to the level logically opposite to the second level (e.g., a high level) from the second level (e.g., a low level). The level of the signal applied to the input terminal IN is the level logically opposite to the first level (e.g., a high level).

In the second phase t2, the first input module 101 stops transmitting the level to the first node N1 under the control of the level of the signal applied to the input terminal IN that is the level logically opposite to the first level. The second input module 102 stops transmitting the level of the clock signal applied to the first clock signal terminal CK1 to the second node N2 under the control of at least the signal applied to the input terminal IN and the clock signal applied to the first clock signal terminal CK1. The interlock module 103 transmits the third level logically opposite to the second level to the second node N2, in response to at least the first level of the first node N1. The levels of the first node N1 and the second node N2 remain unchanged. The first output module 104 transmits the level of the clock signal applied to the second clock signal terminal CK2 to the output terminal OUT, in response to the first level of the first node N1. The second output module 105 is turned off and stops transmitting the level of the power supply signal applied to the first power supply signal terminal VGH to the output terminal OUT, in response to the third level of the second node N2.

As shown in FIG. 2, the first input module 101 (e.g., the first transistor T1) is turned off and stops transmitting the level to the first node N1 under the control of the level of the signal applied to the input terminal IN that is the level logically opposite to the first level (e.g., a high level). The first input unit 1020 (e.g., the second transistor T2) is turned off and stops transmitting the third level (e.g., a high level) of the power supply signal applied to the first power supply signal terminal VGH or the clock signal applied to the second clock signal terminal CK2 to the second terminal of the first input unit 1020. The level of the second terminal of the first input unit 1020 (e.g., the gate of the third transistor T3) remains unchanged. The second input unit 1021 (e.g., the third transistor T3) remains turned off and keeps stopping the transmission of the level of the clock signal applied to the first clock signal terminal CK1 to the second node N2. The first regulation unit 1030 (e.g., the fourth transistor T4) remains turned on and keeps transmitting the level (e.g., a high level) of the power supply signal applied to the first power supply signal terminal VGH as the third level to the second node N2. The second regulation unit 1031 (e.g., the fifth transistor T5) remains turned off. In this way, the levels of the first node N1 and the second node N2 remain unchanged, the second output module 105 (e.g., the seventh transistor T7) remains turned off and keeps stopping the transmission of the level of the power supply signal applied to the first power supply signal terminal VGH to the output terminal OUT, and the first output module 104 (e.g., the sixth transistor T6) remains turned on and keeps transmitting the level of the clock signal applied to the second clock signal terminal CK2 to the output terminal OUT.

In one or more embodiments, as shown in FIG. 3, in the third phase t3, the level of the clock signal applied to the first clock signal terminal CK1 is the second level (e.g., a low level). The level of the clock signal applied to the second clock signal terminal CK2 is the level logically opposite to the second level (e.g., a high level). The level of the signal applied to the input terminal IN is the level logically opposite to the first level (e.g., a high level).

In the third phase t3, the first input module 101 stops transmitting the level to the first node N1 under the control of the level of the signal applied to the input terminal IN that is the level logically opposite to the first level. The second input module 102 transmits the second level of the clock signal applied to the first clock signal terminal CK1 to the second node N2 under the control of at least the signal applied to the input terminal IN and the clock signal applied to the first clock signal terminal CK1. The interlock module 103 transmits the fourth level logically opposite to the first level to the first node N1, in response to at least the second level of the second node N2. The first output module 104 is turned off and stops transmitting the level of the clock signal applied to the second clock signal terminal CK2 to the output terminal OUT, in response to the fourth level of the first node N1. The second output module 105 transmits the level of the power supply signal applied to the first power supply signal terminal VGH to the output terminal OUT, in response to the second level of the second node N2.

As shown in FIG. 2, the first input module 101 (e.g., the first transistor T1) is turned off and stops transmitting the level to the first node N1 under the control of the level of the signal applied to the input terminal IN that is the level logically opposite to the first level (e.g., a high level). The first input unit 1020 (e.g., the second transistor T2) is turned off and stops transmitting the level (e.g., a high level) of the power supply signal applied to the first power supply signal terminal VGH or the clock signal applied to the second clock signal terminal CK2 to the second terminal of the first input unit 1020. After the level of the clock signal applied to the first clock signal terminal CK1 changes from the level logically opposite to the second level (e.g., a high level) to the second level (e.g., a low level), under the action of the first capacitor C1, the level of the second terminal of the first input unit 1020 (e.g., the gate of the third transistor T3) is pulled down, and the second input unit 1021 (e.g., the third transistor T3) is turned on and transmits the level (which may be the second level, e.g., a low level, at this time) of the clock signal applied to the first clock signal terminal CK1 to the second node N2. After the level of the second terminal of the first input unit 1020 (e.g., the gate of the third transistor T3) is pulled down, the second input unit 1021 (e.g., the third transistor T3) may be turned on or may not be fully turned on, as long as the second level (e.g., a low level) of the clock signal applied to the first clock signal terminal CK1 can be transmitted to the second node N2.

The second regulation unit 1031 (e.g., the fifth transistor T5) is turned on and transmits the high level of the power supply signal applied to the first power supply signal terminal VGH as the fourth level to the first node N1, in response to the second level (e.g., a low level) of the second node N2, and the first output module 104 (e.g., the sixth transistor T6) is turned off and stops transmitting the level of the clock signal applied to the second clock signal terminal CK2 to the output terminal OUT, in response to the fourth level (e.g., a high level) of the first node N1. The first regulation unit 1030 (e.g., the fourth transistor T4) is turned off and stops transmitting the level of the power supply signal applied to the first power supply signal terminal VGH as the third level to the second node N2, in response to the fourth level (e.g., a high level) of the first node N1, and the second output module 105 (e.g., the seventh transistor T7) is turned on and transmits the high level of the power supply signal applied to the first power supply signal terminal VGH to the output terminal OUT, in response to the second level (e.g., a low level) of the second node N2.

In one or more embodiments, as shown in FIG. 3, in the fourth phase t4, the level of the clock signal applied to the first clock signal terminal CK1 is the level logically opposite to the second level (e.g., a high level). The level of the clock signal applied to the second clock signal terminal CK2 changes from the level logically opposite to the second level (e.g., a high level) to the second level (e.g., a low level), and then back to the level logically opposite to the second level (e.g., a high level) from the second level (e.g., a low level). The level of the signal applied to the input terminal IN is the level logically opposite to the first level (e.g., a high level).

In the fourth phase t4, the first input module 101 stops transmitting the level to the first node N1 under the control of the level of the signal applied to the input terminal IN that is the level logically opposite to the first level. The second input module 102 stops transmitting the level of the clock signal applied to the first clock signal terminal CK1 to the second node N2 under the control of at least the signal applied to the input terminal IN and the clock signal applied to the first clock signal terminal CK1. The levels of the first node N1 and the second node N2 remain unchanged. The interlock module 103 keeps transmitting the fourth level logically opposite to the first level to the first node N1, in response to at least the second level of the second node N2. The first output module 104 is turned off and stops transmitting the level of the clock signal applied to the second clock signal terminal CK2 to the output terminal OUT, in response to the fourth level of the first node N1. The second output module transmits the level of the power supply signal applied to the first power supply signal terminal VGH to the output terminal OUT, in response to the second level of the second node N2.

As shown in FIG. 2, the first input module 101 (e.g., the first transistor T1) is turned off and stops transmitting the level to the first node N1 under the control of the level of the signal applied to the input terminal IN that is the level logically opposite to the first level (e.g., a high level). The first input unit 1020 (e.g., the second transistor T2) is turned off and stops transmitting the third level (e.g., a high level) of the power supply signal applied to the first power supply signal terminal VGH or the clock signal applied to the second clock signal terminal CK2 to the second terminal of the first input unit 1020. After the level of the first clock signal terminal CK1 changes from the second level (e.g., a low level) to the third level (e.g., a high level), under the action of the first capacitor C1, the level of the second terminal of the first input unit 1020 (e.g., the gate of the third transistor T3) is pulled up, and the second input unit 1021 (e.g., the third transistor T3) is turned off and stops transmitting the level to the second node N2. The second regulation unit 1031 (e.g., the fifth transistor T5) remains turned on and keeps transmitting the level (e.g., a high level) of the power supply signal applied to the first power supply signal terminal VGH as the fourth level to the first node N1. The first regulation unit 1030 (e.g., the fourth transistor T4) remains turned off and keeps stopping the transmission of the level of the power supply signal applied to the first power supply signal terminal VGH as the third level to the second node N2. In this way, the levels of the first node N1 and the second node N2 remain unchanged, the first output module 104 (e.g., the sixth transistor T6) remains turned off and stops transmitting the level of the clock signal applied to the second clock signal terminal CK2 to the output terminal OUT, and the second output module 105 (e.g., the seventh transistor T7) remains turned on and keeps transmitting the level (e.g., a high level) of the power supply signal applied to the first power supply signal terminal VGH to the output terminal OUT.

After the fourth phase t4, the shift register repeatedly and alternately performs the processes of the third phase t3 and the fourth phase t4 until the first level (e.g., a low level) is input into the input terminal IN again, and then the first phase t1 is performed again.

In some embodiments of the present application, as shown in FIG. 4, FIG. 4 is a schematic structural diagram of another shift register according to an embodiment of the present application. The first input module 101 may further be electrically connected to a second power supply signal terminal VGL or the first clock signal terminal CK1. For example, the first terminal of the first input module 101 is electrically connected to the second power supply signal terminal VGL or the first clock signal terminal CK1. The first input module 101 is configured to transmit a level of a power supply signal applied to the second power supply signal terminal VGL or the second level of the clock signal applied to the first clock signal terminal CK1 as the first level to the first node N1 under the control of the signal applied to the input terminal IN.

The first input module 101 is turned on and transmits the level of the power supply signal applied to the second power supply signal terminal VGL or the second level of the clock signal applied to the first clock signal terminal CK1 as the first level to the first node N1 under the control of the first level of the signal applied to the input terminal IN. The first input module 101 is turned off and stops transmitting the level of the power supply signal applied to the second power supply signal terminal VGL or the level of the clock signal applied to the first clock signal terminal CK1 to the first node N1 under the control of the level of the signal applied to the input terminal IN that is the level logically opposite to the first level.

In one or more embodiments, the gate of the first transistor T1 is electrically connected to the input terminal IN, the first electrode of the first transistor T1 is electrically connected to the second power supply signal terminal VGL or the first clock signal terminal CK1, and the second electrode of the first transistor T1 is electrically connected to the first node N1. Compared with the structure shown in FIG. 4, the gate and the first electrode of the first transistor T1 in FIG. 2 share a signal, thereby reducing control signals for the first input module 101.

In the case that the first level of the first node N1 is a low level, the level of the power supply signal applied to the second power supply signal terminal VGL and the second level of the clock signal applied to the first clock signal terminal CK1 are both low levels. In the case that the first level of the first node N1 is a high level, the level of the power supply signal applied to the second power supply signal terminal VGL and the second level of the clock signal applied to the first clock signal terminal CK1 are both high levels.

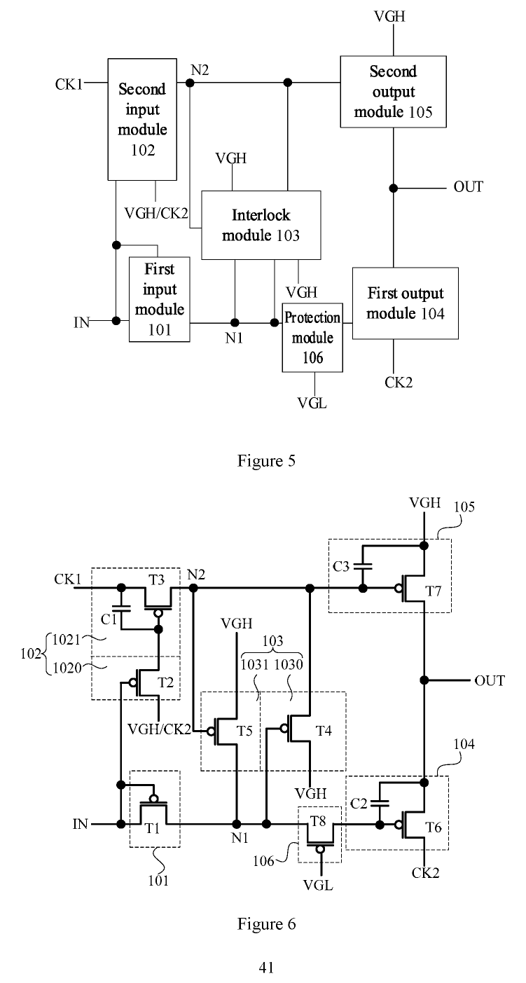

In some embodiments of the present application, as shown in FIG. 5, FIG. 5 is a schematic structural diagram of another shift register according to an embodiment of the present application. The shift register may further include a protection module 106. The protection module 106 is connected between the first node N1 and the first output module 104. The protection module 106 is configured to transmit the first level of the first node N1 to the first output module 104 under the control of the power supply signal applied to the second power supply signal terminal VGL.

The level of the power supply signal applied to the second power supply signal terminal VGL may be a turn-on level for the protection module 106. The protection module 106 may keep turned on under the control of the power supply signal applied to the second power supply signal terminal VGL. For example, one of the level of the power supply signal applied to the first power supply signal terminal VGH and the level of the power supply signal applied to the second power supply signal terminal VGL is a high level, and the other is a low level. For example, the level of the power supply signal applied to the first power supply signal terminal VGH is a high level, and the level of the power supply signal applied to the second power supply signal terminal VGL is a low level.

In some examples, as shown in FIG. 6, FIG. 6 is a schematic structural diagram of another shift register according to an embodiment of the present application. The protection module 106 includes an eighth transistor T8. A first electrode of the eighth transistor T8 is electrically connected to the first node N1, a gate of the eighth transistor T8 is electrically connected to the second power supply signal terminal VGL, and a second electrode of the eighth transistor T8 is electrically connected to the first output module 104 (e.g., the gate of the sixth transistor T6).

Since the second capacitor C2 is present between the gate and the first electrode of the sixth transistor T6, a gate voltage of the sixth transistor T6 is low. The gate of the sixth transistor T6 is electrically connected to the first node N1 via the eighth transistor T8, which can prevent a high level of the first node N1 from damaging the sixth transistor T6.

In one or more embodiments, the interlock module 103 is further electrically connected to the first clock signal terminal CK1.The interlock module 103 transmits the level of the power supply signal applied to the first power supply signal terminal VGH or the level of the clock signal applied to the second clock signal terminal CK2 as the third level to the second node N2, in response to the first level of the first node N1 and the second level of the clock signal applied to the first clock signal terminal CK1. The interlock module 103 transmits the level of the power supply signal applied to the first power supply signal terminal VGH or the level of the clock signal applied to the second clock signal terminal CK2 as the fourth level to the first node N1, in response to the second level of the second node N2 and the second level of the clock signal applied to the first clock signal terminal CK1.

In one or more embodiments, the first regulation unit 1030 is further electrically connected to the first clock signal terminal CK1. The first regulation unit 1030 transmits the level of the power supply signal applied to the first power supply signal terminal VGH or the level of the clock signal applied to the second clock signal terminal CK2 as the third level to the second node N2, in response to the first level of the first node N1 and the level of the clock signal applied to the first clock signal terminal CK1 that is the second level. The second regulation unit 1031 is further electrically connected to the first clock signal terminal CK1. The second regulation unit 1031 transmits the level of the power supply signal applied to the first power supply signal terminal VGH or the level of the clock signal applied to the second clock signal terminal CK2 as the fourth level to the first node N1, in response to the second level of the second node N2 and the level of the clock signal applied to the first clock signal terminal CK1 that is the second level. The first regulation unit 1030 and the second regulation unit 1031 are connected to the first power supply signal terminal VGH, which provides more reliable operation compared with being connected to the second clock signal terminal CK2.

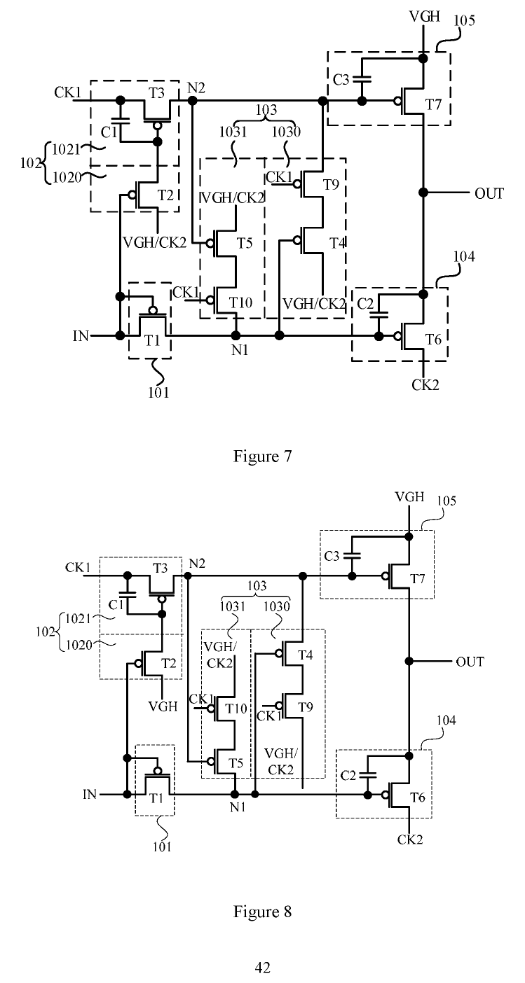

Certainly, the present application is not limited thereto. In some other embodiments, as shown in FIG. 7, FIG. 7 is a schematic structural diagram of another shift register according to an embodiment of the present application. The first regulation unit 1030 further includes a ninth transistor T9, and/or the second regulation unit 1031 further includes a tenth transistor T10.

In one or more embodiments, a gate of the ninth transistor T9 is electrically connected to the first clock signal terminal CK1, a first electrode of the ninth transistor T9 is electrically connected to the second node N2, and a second electrode of the ninth transistor T9 is electrically connected to the second electrode of the fourth transistor T4. For example, the first electrode of the fourth transistor T4 is electrically connected to the first power supply signal terminal VGH or the second clock signal terminal CK2.

In one or more embodiments, as shown in FIG. 7, a gate of the tenth transistor T10 is electrically connected to the first clock signal terminal CK1, a first electrode of the tenth transistor T10 is electrically connected to the first node N1, and a second electrode of the tenth transistor T10 is electrically connected to the second electrode of the fifth transistor T5. For example, the first electrode of the fifth transistor T5 is electrically connected to the first power supply signal terminal VGH or the second clock signal terminal CK2.

In some other embodiments, as shown in FIG. 8, FIG. 8 is a schematic structural diagram of another shift register according to an embodiment of the present application. For example, the gate of the ninth transistor T9 is electrically connected to the first clock signal terminal CK1, the first electrode of the ninth transistor T9 is electrically connected to the first power supply signal terminal VGH or the second clock signal terminal CK2, and the second electrode of the ninth transistor T9 is electrically connected to the first electrode of the fourth transistor T4.

In one or more embodiments, the gate of the tenth transistor T10 is electrically connected to the first clock signal terminal CK1, the first electrode of the tenth transistor T10 is electrically connected to the first power supply signal terminal VGH or the second clock signal terminal CK2, and the second electrode of the tenth transistor T10 is electrically connected to the first electrode of the fifth transistor T5.

In the first phase t1, the first regulation unit 1030 is turned on in response to the first level (e.g., a low level) of the first node N1 and the level of the clock signal applied to the first clock signal terminal CK1 that is the second level (e.g., a low level). For example, the fourth transistor T4 is turned on in response to the first level (e.g., a low level) of the first node N1, and the ninth transistor T9 is turned on in response to the level of the clock signal applied to the first clock signal terminal CK1 that is the second level (e.g., a low level). The level of the power supply signal applied to the first power supply signal terminal VGH or the level of the clock signal applied to the second clock signal terminal CK2 (which may be a high level at this time) is transmitted as the third level to the second node N2. The second regulation unit 1031 is turned off in response to the third level (e.g., a high level) of the second node N2. For example, the fifth transistor T5 is turned off in response to the third level (e.g., a high level) of the second node N2. Although the tenth transistor T10 is turned on in response to the level of the clock signal applied to the first clock signal terminal CK1 that is the second level (e.g., a low level), the turned-off state of the second regulation unit 1031 is not affected.

In the second phase t2, the first regulation unit 1030 (e.g., the ninth transistor T9) is turned off in response to the level of the clock signal applied to the first clock signal terminal CK1 that is the level logically opposite to the second level. The second regulation unit 1031 (e.g., the fifth transistor T5 and the tenth transistor T10) is turned off. In this way, the levels of the first node N1 and the second node N2 remain unchanged.

In the third phase t3, the second regulation unit 1031 is turned on. For example, the fifth transistor T5 is turned on in response to the second level (e.g., a low level) of the second node N2, and the tenth transistor T10 is turned on in response to the level of the clock signal applied to the first clock signal terminal CK1 that is the second level (e.g., a low level). The level of the power supply signal applied to the first power supply signal terminal VGH or the level of the clock signal applied to the second clock signal terminal CK2 (which may be a high level at this time) is transmitted as the fourth level to the first node N1. The first regulation unit 1030 is turned off. For example, the fourth transistor T4 is turned off in response to the fourth level (e.g., a high level) of the first node N1. Although the ninth transistor T9 is turned on in response to the level of the clock signal applied to the first clock signal terminal CK1 that is the second level (e.g., a low level), the turned-off state of the first regulation unit 1030 is not affected.

In the fourth phase t4, the first regulation unit 1030 is turned off. For example, the fourth transistor T4 and the ninth transistor T9 are turned off. The second regulation unit 1031 is turned off. For example, the tenth transistor T10 is turned off. In this way, the levels of the first node N1 and the second node N2 remain unchanged. The fifth transistor T5 is turned on, but the turned-off state of the second regulation unit 1031 is not affected.

Based on this, the interlock module 103 transmits the level of the power supply signal applied to the first power supply signal terminal VGH (e.g., a high level) as the third level to the second node N2, in response to the first level of the first node N1 and the level of the clock signal applied to the first clock signal terminal CK1 (which may be the second level at this time), and transmits the level of the power supply signal applied to the first power supply signal terminal VGH (e.g., a high level) as the fourth level to the first node N1, in response to the second level of the second node N2 and the level of the clock signal applied to the first clock signal terminal CK1 that is the second level, thereby further enhancing the stability of a shift register circuit.

In the structures shown in FIG. 7 and FIG. 8, the interlock module 103 is electrically connected to the first power supply signal terminal VGH. Compared with being electrically connected to the second clock signal terminal CK2, the interlock module 103 exhibits higher stability and avoids the erroneous pulling down for the first node N1 and the second node N2. In the case that the first level and the second level are low levels, the first regulation unit 1030 is configured to pull up the level of the first node N1 to a high level, and the second regulation unit 1031 is configured to pull up the level of the second node N2 to a high level. However, the present application is not limited thereto. In the case that the first level and the second level are high levels, the first regulation unit 1030 is configured to pull down the level of the first node N1 to a low level, and the second regulation unit 1031 is configured to pull down the level of the second node N2 to a low level. Details are not repeated herein.

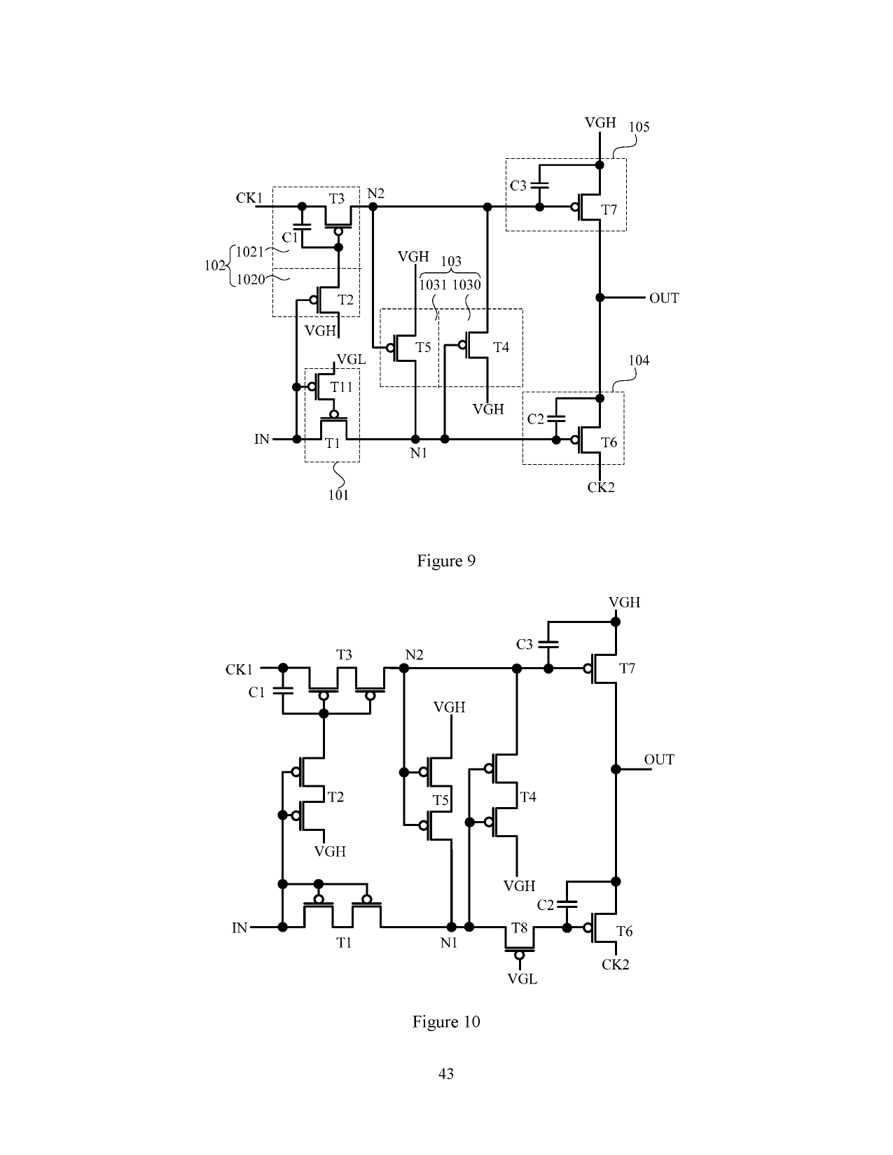

In some other embodiments, as shown in FIG. 9, FIG. 9 is a schematic structural diagram of another shift register according to an embodiment of the present application. The first input module 101 may further include an eleventh transistor T11. A first electrode of the first transistor T1 is electrically connected to the input terminal IN, a second electrode of the first transistor T1 is electrically connected to the first node N1, the gate of the first transistor T1 is electrically connected to a first electrode of the eleventh transistor T11, a second electrode of the eleventh transistor T11 is electrically connected to the second power supply signal terminal VGL, and a gate of the eleventh transistor T11 is electrically connected to the input terminal IN. Certainly, in some other embodiments, the first electrode of the first transistor T1 may be electrically connected to the second power supply signal terminal VGL or the first clock signal terminal CK1.

The eleventh transistor T11 is turned on under the control of the level of the signal applied to the input terminal IN that is the first level (e.g., a low level). The turned-on eleventh transistor T11 transmits the level (e.g., a low level) of the power supply signal applied to the second power supply signal terminal VGL to the gate of the first transistor T1, controlling the first transistor T1 to be turned on, and the first input module 101 is turned on. The turned-on first input module 101 (e.g., the first transistor T1) transmits the first level (e.g., a low level) to the first node N1. The eleventh transistor T11 is turned off under the control of the level of the signal applied to the input terminal IN that is the level logically opposite to the first level (e.g., a high level). The turned-off eleventh transistor T11 stops transmitting the level (e.g., a low level) of the power supply signal applied to the second power supply signal terminal VGL to the gate of the first transistor T1, and the first transistor T1 is turned off. In this way, the first input module 101 is turned off, and the turned-off first input module 101 (e.g., the first transistor T1) transmits the level of the signal applied to the input terminal IN to the first node N1.

In some other embodiments, as shown in FIG. 10, FIG. 10 is a schematic structural diagram of each module of another shift register according to an embodiment of the present application. At least one of the first transistor T1, the second transistor T2, the third transistor T3, the fourth transistor T4, or the fifth transistor T5 includes a dual-gate transistor, thereby reducing the impact of leakage current on the transistors, and thus enhancing the stability of the shift register circuit.

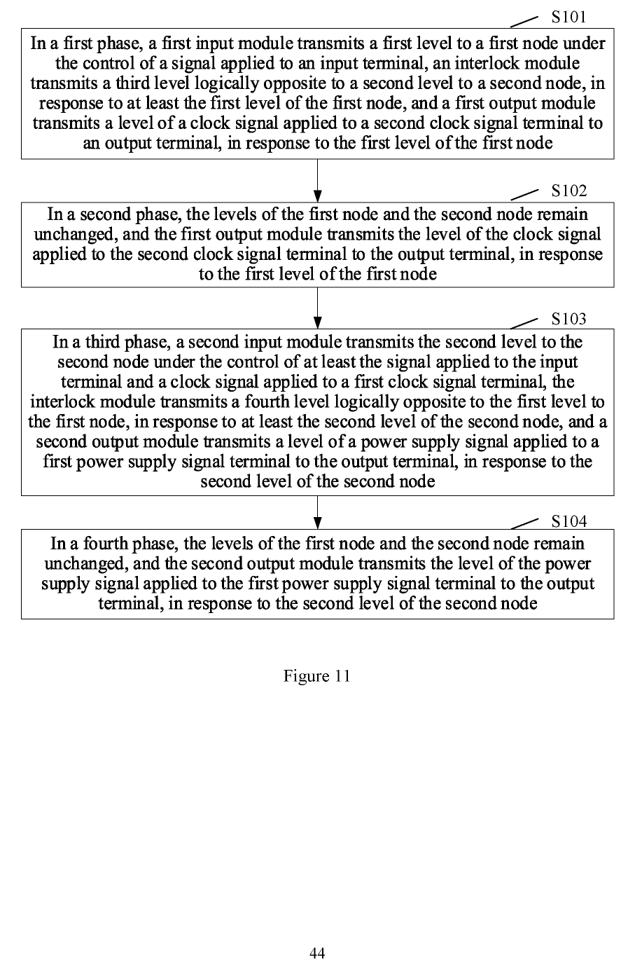

As an optional implementation of the disclosure of the present application, an embodiment of the present application discloses a driving method for a shift register. The driving method may be used to drive a shift register according to any one of the embodiments of the present application. As shown in FIG. 11, FIG. 11 is a flowchart of a driving method for a shift register according to an embodiment of the present application. The driving method includes the following steps.

S101: In a first phase, a first input module transmits a first level to a first node under the control of a signal applied to an input terminal, an interlock module transmits a third level logically opposite to a second level to a second node, in response to at least the first level of the first node, and a first output module transmits a level of a clock signal applied to a second clock signal terminal to an output terminal, in response to the first level of the first node.

In the first phase t1, the first input module 101 is turned on and transmits the first level to the first node N1 under the control of the level of the signal applied to the input terminal IN that is the first level. The second input module 102 stops transmitting the level of the clock signal applied to the first clock signal terminal CK1 to the second node N2 under the control of at least the level of the signal applied to the input terminal IN that is the first level. The interlock module 103 transmits the third level logically opposite to the second level to the second node N2, in response to at least the first level of the first node N1. The first output module 104 transmits the level of the clock signal applied to the second clock signal terminal CK2 to the output terminal OUT, in response to the first level of the first node N1. The second output module 105 is turned off and stops transmitting the level of the power supply signal applied to the first power supply signal terminal VGH to the output terminal OUT, in response to the third level of the second node N2.

S102: In a second phase, the levels of the first node and the second node remain unchanged, and the first output module transmits the level of the clock signal applied to the second clock signal terminal to the output terminal, in response to the first level of the first node.

In the second phase t2, the first input module 101 is turned off and stops transmitting the level to the first node N1 under the control of the level of the signal applied to the input terminal IN that is the level logically opposite to the first level. The second input module 102 stops transmitting the level of the clock signal applied to the first clock signal terminal CK1 to the second node N2 under the control of at least the level of the clock signal applied to the first clock signal terminal CK1 that is the level logically opposite to the second level. The interlock module 103 transmits the third level logically opposite to the second level to the second node N2, in response to at least the first level of the first node N1. The levels of the first node N1 and the second node N2 remain unchanged. The first output module 104 is turned on and transmits the level of the clock signal applied to the second clock signal terminal CK2 to the output terminal OUT, in response to the first level of the first node N1. The second output module 105 is turned off and stops transmitting the level of the power supply signal applied to the first power supply signal terminal VGH to the output terminal OUT, in response to the third level of the second node N2.

S103: In a third phase, a second input module transmits the second level to the second node under the control of at least the signal applied to the input terminal and a clock signal applied to a first clock signal terminal, the interlock module transmits a fourth level logically opposite to the first level to the first node, in response to at least the second level of the second node, and a second output module transmits a level of a power supply signal applied to a first power supply signal terminal to the output terminal, in response to the second level of the second node.

In the third phase t3, the first input module 101 is turned off and stops transmitting the level to the first node N1 under the control of the level of the signal applied to the input terminal IN that is the level logically opposite to the first level. The second input module 102 transmits the level (e.g., the second level) of the clock signal applied to the first clock signal terminal CK1 to the second node N2 under the control of at least the level of the signal applied to the input terminal IN that is the level logically opposite to the first level and the level of the clock signal applied to the first clock signal terminal CK1 that is the second level. The interlock module 103 transmits the fourth level logically opposite to the first level to the first node N1, in response to at least the second level of the second node N2. The first output module 104 is turned off and stops transmitting the level of the clock signal applied to the second clock signal terminal CK2 to the output terminal OUT, in response to the fourth level of the first node N1. The second output module 105 is turned on and transmits the level of the power supply signal applied to the first power supply signal terminal VGH to the output terminal OUT, in response to the second level of the second node N2.

S104: In a fourth phase, the levels of the first node and the second node remain unchanged, and the second output module transmits the level of the power supply signal applied to the first power supply signal terminal to the output terminal, in response to the second level of the second node.

In the fourth phase t4, the first input module 101 is turned off and stops transmitting the level to the first node N1 under the control of the level of the signal applied to the input terminal IN that is the level logically opposite to the first level. The second input module 102 stops transmitting the level of the clock signal applied to the first clock signal terminal CK1 to the second node N2 under the control of at least the level of the signal applied to the input terminal IN that is the level logically opposite to the first level and the level of the clock signal applied to the first clock signal terminal CK1 that is the level logically opposite to the second level. The levels of the first node N1 and the second node N2 remain unchanged. The interlock module 103 keeps transmitting the fourth level logically opposite to the first level to the first node N1, in response to at least the second level of the second node N2. The first output module 104 is turned off and stops transmitting the level of the clock signal applied to the second clock signal terminal CK2 to the output terminal OUT, in response to the fourth level of the first node N1. The second output module is turned on and transmits the level of the power supply signal applied to the first power supply signal terminal VGH to the output terminal OUT, in response to the second level of the second node N2.

After the fourth phase t4, the shift register repeatedly and alternately performs the processes of the third phase t3 and the fourth phase t4 until the first level (e.g., a low level) is input into the input terminal IN again, and the input terminal IN re-enters the first phase t1.

For shift registers with modules of different structures, states of the modules, such as states of transistors, vary during the same phase. However, functions of the modules remain the same, and accordingly, details are not repeated herein.

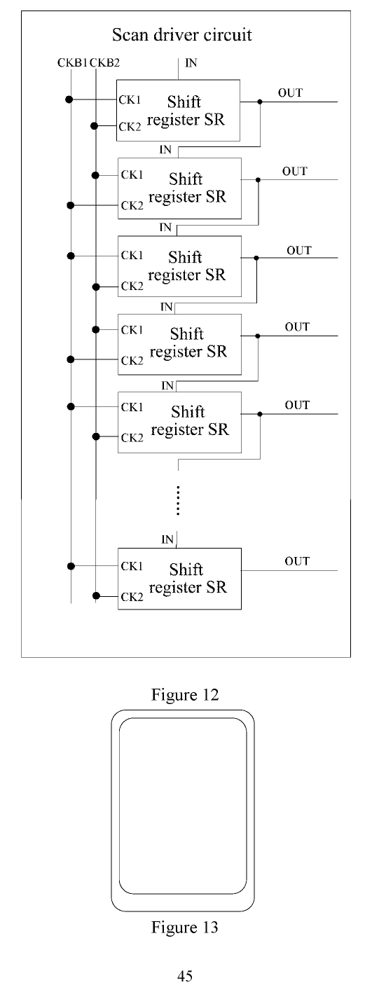

As an optional implementation of the disclosure of the present application, an embodiment of the present application discloses a scan driver circuit. As shown in FIG. 12, FIG. 12 is a schematic structural diagram of a scan driver circuit according to an embodiment of the present application. The scan driver circuit includes a plurality of cascaded shift registers SR each including a shift register according to any one of the above-described embodiments.

Among two adjacent stages of shift registers SR, an output terminal OUT of the preceding shift register SR is electrically connected to an input terminal IN of the subsequent shift register SR. Among the two adjacent stages of shift registers SR, a first clock signal terminal CK1 of the preceding shift register SR and a second clock signal terminal CK2 of the subsequent shift register SR are electrically connected to a same clock signal line, while the second clock signal terminal CK2 of the preceding shift register SR and the first clock signal terminal CK1 of the subsequent shift register SR are electrically connected to another same clock signal line. The first clock signal terminal CK1 and the second clock signal terminal CK2 of a same stage of shift register SR are electrically connected to different clock signal lines, such as a first clock signal line CKB1 and a second clock signal line CKB2.

As an optional implementation of the disclosure of the present application, an embodiment of the present application discloses a display panel. As shown in FIG. 13, FIG. 13 is a schematic structural diagram of a display panel according to an embodiment of the present application. The display panel includes a scan driver circuit according to any one of the above-described embodiments.

The display panel includes an active area and a non-active area. In some embodiments, the scan driver circuit is located in the non-active area on one side of the active area. In some other embodiments, the scan driver circuit is located in the non-active area on two opposite sides of the active area. Details are not repeated herein.

As an optional implementation of the disclosure of the present application, an embodiment of the present application discloses a display device. The display device includes a display panel according to any one of the above-described embodiments. The display device may be a smartphone, a wearable product, a computer, a television, an automotive display device, or any other display devices with a display function, which is not specifically limited in the present application.

The technical features of the above-described embodiments may be combined arbitrarily. For brevity of description, all the possible combinations of the technical features in the above-described embodiments are not described. However, as long as there is no contradiction between the combinations of these technical features, they shall all fall within the scope of the specification.

1. A shift register, comprising:
a first input module, electrically connected to at least an input terminal and a first node, the first input module being configured to transmit a first level to the first node under the control of a signal applied to the input terminal;
a second input module, electrically connected to at least the input terminal, a second node, and a first clock signal terminal, the second input module being configured to transmit a second level of a clock signal applied to the first clock signal terminal to the second node under the control of at least the signal applied to the input terminal and the clock signal applied to the first clock signal terminal;
an interlock module, electrically connected to at least the first node and the second node, the interlock module being configured to transmit a third level logically opposite to the second level to the second node, in response to at least the first level of the first node, and transmit a fourth level logically opposite to the first level to the first node, in response to at least the second level of the second node;
a first output module, electrically connected to a second clock signal terminal and an output terminal, the first output module being configured to transmit a level of a clock signal applied to the second clock signal terminal to the output terminal, in response to the first level of the first node; and
a second output module, electrically connected to the second node, a first power supply signal terminal, and the output terminal, the second output module being configured to transmit a level of a power supply signal applied to the first power supply signal terminal to the output terminal, in response to the second level of the second node.

2. The shift register according to claim 1, wherein the first input module is configured to transmit the first level of the signal applied to the input terminal to the first node under the control of the signal applied to the input terminal; or,
the first input module is further electrically connected to a second power supply signal terminal or the first clock signal terminal, and the first input module is configured to transmit the second level of the clock signal applied to the first clock signal terminal or a level of a power supply signal applied to the second power supply signal terminal as the first level to the first node under the control of the signal applied to the input terminal.

3. The shift register according to claim 2, wherein the first input module comprises a first transistor; and
a gate and a first electrode of the first transistor are electrically connected to the input terminal, and a second electrode of the first transistor is electrically connected to the first node; or,
the gate of the first transistor is electrically connected to the input terminal, the first electrode of the first transistor is electrically connected to the second power supply signal terminal or the first clock signal terminal, and the second electrode of the first transistor is electrically connected to the first node.

4. The shift register according to claim 3, wherein the first transistor comprises a dual-gate transistor.

5. The shift register according to claim 1, wherein the second input module comprises a first input unit and a second input unit;
a control terminal of the first input unit is electrically connected to the input terminal, a first terminal of the first input unit is electrically connected to the first power supply signal terminal or the second clock signal terminal, and the first input unit is configured to transmit the level of the power supply signal applied to the first power supply signal terminal or the clock signal applied to the second clock signal terminal to a second terminal of the first input unit under the control of the signal applied to the input terminal; and
the second input unit is electrically connected to the second terminal of the first input unit, the second node, and the first clock signal terminal, and the second input unit is configured to transmit the second level of the clock signal applied to the first clock signal terminal to the second node under the control of the level of the second terminal of the first input unit and the clock signal applied to the first clock signal terminal.

6. The shift register according to claim 5, wherein the first input unit comprises a second transistor, a gate of the second transistor being electrically connected to the input terminal, a first electrode of the second transistor being electrically connected to the first power supply signal terminal or the second clock signal terminal, and a second electrode of the second transistor being the second terminal of the first input unit; and
the second input unit comprises a third transistor and a first capacitor, a gate of the third transistor being electrically connected to the second terminal of the first input unit, a first electrode of the third transistor being electrically connected to the first clock signal terminal, and a second electrode of the third transistor being electrically connected to the second node; and a first electrode of the first capacitor being electrically connected to the first electrode of the third transistor, and a second electrode of the first capacitor being electrically connected to the gate of the third transistor.

7. The shift register according to claim 6, wherein the second transistor or the third transistor comprises a dual-gate transistor, or the second transistor comprises a dual-gate transistor and the third transistor comprises a dual-gate transistor.

8. The shift register according to claim 1, wherein the interlock module comprises a first regulation unit and a second regulation unit;
the first regulation unit is electrically connected to at least the first power supply signal terminal, the first node, and the second node, and the first regulation unit is configured to transmit the level of the power supply signal applied to the first power supply signal terminal as the third level to the second node, in response to at least the first level of the first node; and
the second regulation unit is electrically connected to at least the first power supply signal terminal, the first node, and the second node, and the second regulation unit is configured to transmit the level of the power supply signal applied to the first power supply signal terminal as the fourth level to the first node, in response to at least the second level of the second node.

9. The shift register according to claim 8, wherein the first regulation unit comprises a fourth transistor, a gate of the fourth transistor being electrically connected to the first node, a first electrode of the fourth transistor being electrically connected to the first power supply signal terminal, and a second electrode of the fourth transistor being electrically connected to the second node; and
the second regulation unit comprises a fifth transistor, a gate of the fifth transistor being electrically connected to the second node, a first electrode of the fifth transistor being electrically connected to the first power supply signal terminal, and a second electrode of the fifth transistor being electrically connected to the first node.

10. The shift register according to claim 9, wherein the fourth transistor or the fifth transistor comprises a dual-gate transistor, or the fourth transistor comprises a dual-gate transistor and the fifth transistor comprises a dual-gate transistor.

11. The shift register according to claim 1, wherein the first output module comprises a sixth transistor, a gate of the sixth transistor being electrically connected to the first node, a first electrode of the sixth transistor being electrically connected to the second clock signal terminal, and a second electrode of the sixth transistor being electrically connected to the output terminal;
and, the second output module comprises a seventh transistor, a gate of the seventh transistor being electrically connected to the second node, a first electrode of the seventh transistor being electrically connected to the first power supply signal terminal, and a second electrode of the seventh transistor being electrically connected to the output terminal.

12. The shift register according to claim 11, wherein the first output module further comprises a second capacitor, a first electrode of the second capacitor being electrically connected to the second electrode of the sixth transistor, and a second electrode of the second capacitor being electrically connected to the gate of the sixth transistor.

13. The shift register according to claim 11, wherein
the second output module further comprises a third capacitor, a first electrode of the third capacitor being electrically connected to the first electrode of the seventh transistor, and a second electrode of the third capacitor being electrically connected to the gate of the seventh transistor.

14. The shift register according to claim 1, further comprising a protection module, connected between the first node and the first output module, the protection module being configured to transmit the first level of the first node to the first output module under the control of a power supply signal applied to a second power supply signal terminal.

15. The shift register according to claim 14, wherein the protection module comprises an eighth transistor, a first electrode of the eighth transistor being electrically connected to the first node, a gate of the eighth transistor being electrically connected to the second power supply signal terminal, and a second electrode of the eighth transistor being electrically connected to the first output module.

16. The shift register according to claim 1, wherein the interlock module comprises a first regulation unit and a second regulation unit;
the first regulation unit is electrically connected to at least the first clock signal terminal, the first node, and the second node, and the first regulation unit is further electrically connected to the first power supply signal terminal or the second clock signal terminal, and is configured to transmit the level of the power supply signal applied to the first power supply signal terminal or the level of the clock signal applied to the second clock signal terminal as the third level to the second node, in response to the first level of the first node and the second level of the clock signal applied to the first clock signal terminal; and
the second regulation unit is electrically connected to at least the first clock signal terminal, the first node, and the second node, and the second regulation unit is further electrically connected to the first power supply signal terminal or the second clock signal terminal , and is configured to transmit the level of the power supply signal applied to the first power supply signal terminal or the level of the clock signal applied to the second clock signal terminal as the fourth level to the first node, in response to the second level of the second node and the second level of the clock signal applied to the first clock signal terminal.

17. The shift register according to claim 16, wherein the first regulation unit comprises a fourth transistor, a gate of the fourth transistor being electrically connected to the first node; and
the second regulation unit comprises a fifth transistor, a gate of the fifth transistor being electrically connected to the second node,
the first regulation unit further comprises a ninth transistor, and the second regulation unit further comprises a tenth transistor;
a gate of the ninth transistor is electrically connected to the first clock signal terminal, a first electrode of the ninth transistor is electrically connected to the second node, a second electrode of the ninth transistor is electrically connected to a second electrode of the fourth transistor, and a first electrode of the fourth transistor is electrically connected to the first power supply signal terminal or the second clock signal terminal;
or, the gate of the ninth transistor is electrically connected to the first clock signal terminal, the first electrode of the ninth transistor is electrically connected to the first power supply signal terminal or the second clock signal terminal, the second electrode of the ninth transistor is electrically connected to the first electrode of the fourth transistor, and the second electrode of the fourth transistor is electrically connected to the second node; and
a gate of the tenth transistor is electrically connected to the first clock signal terminal, a first electrode of the tenth transistor is electrically connected to the first node, a second electrode of the tenth transistor is electrically connected to the second electrode of the fifth transistor, and the first electrode of the fifth transistor is electrically connected to the first power supply signal terminal or the second clock signal terminal;
or, the gate of the tenth transistor is electrically connected to the first clock signal terminal, the first electrode of the tenth transistor is electrically connected to the first power supply signal terminal or the second clock signal terminal, the second electrode of the tenth transistor is electrically connected to the first electrode of the fifth transistor, and the second electrode of the fifth transistor is electrically connected to the first node.

18. The shift register according to claim 2, wherein one of the level of the power supply signal applied to the first power supply signal terminal and the level of the power supply signal applied to the second power supply signal terminal is a high level, and the other is a low level;
or, the clock signal applied to the first clock signal terminal and the clock signal applied to the second clock signal terminal have a same frequency but opposite phases;
or, the first level and the second level are logically the same.

19. A display panel, comprising a scan driver circuit, wherein the scan driver circuit comprises a plurality of cascaded shift registers each comprising a shift register according to claim 1.

20. A driving method for a shift register, for use in driving a shift register according to claim 1, the driving method comprising:
in a first phase, the first input module transmits a first level to the first node under the control of a signal applied to the input terminal, the interlock module transmits a third level logically opposite to a second level to the second node, in response to at least the first level of the first node, and the first output module transmits a level of a clock signal applied to the second clock signal terminal to the output terminal, in response to the first level of the first node;
in a second phase, the levels of the first node and the second node remain unchanged, and the first output module transmits the level of the clock signal applied to the second clock signal terminal to the output terminal, in response to the first level of the first node;
in a third phase, the second input module transmits the second level of the clock signal applied to the first clock signal terminal to the second node under the control of at least the signal applied to the input terminal and the clock signal applied to the first clock signal terminal, the interlock module transmits a fourth level logically opposite to the first level to the first node, in response to at least the second level of the second node, and the second output module transmits the level of the power supply signal applied to the first power supply signal terminal to the output terminal, in response to the second level of the second node; and
in a fourth phase, the levels of the first node and the second node remain unchanged, and the second output module transmits the level of the power supply signal applied to the first power supply signal terminal to the output terminal, in response to the second level of the second node.
